(19) United States
(12) Patent Application Publication
(10) Pub. No.: US 2021/0286004 A1
(43) Pub. Date: Sep. 16, 2021

(54) SYSTEM FOR TEST AND MEASUREMENT INSTRUMENTATION DATA COLLECTION AND EXCHANGE

(71) Applicant: Tektronix, Inc., Beaverton, OR (US)

(72) Inventors: Frederick B. Kuhlman, III, Nashville, TN (US); Shane L. Arnold, Beaverton, OR (US)

(73) Assignee: Tektronix, Inc., Beaverton, OR (US)

(21) Appl. No.: 17/332,873

(22) Filed: May 27, 2021

Related U.S. Application Data
(63) Continuation-in-part of application No. 16/695,980, filed on Nov. 26, 2019.
(60) Provisional application No. 63/030,845, filed on May 27, 2020.
(60) Provisional application No. 62/772,051, filed on Nov. 27, 2018.

(51) Int. Cl. G01R 31/317

(52) U.S. Cl. CPC G01R 31/31718; G01R 31/31722

(57) ABSTRACT

A method of capturing instrument data using a communications device includes recognizing an action performed by a user on the communication device, one of either transmitting or receiving a trigger message between the communications device and at least one instrument, storing instrument data in a memory on the at least one instrument, and transmitting the instrument data and user information to a network. A test system includes a test and measurement device having at least one communications link, a memory, and a processor configured to execute instructions that cause the processor to receive a message through the communications link, save instrument data into the memory, and transmit the instrument data to a remote location; and a communications device having at least one communications link, a memory, and a processor configured to execute instructions that cause the processor to recognize an action performed by a user, send the message to the test and measurement device, store associated information including user information, and transmit the user information to the remote location.

### RELATED APPLICATIONS

This application is a continuation-in-part of U.S. patent application Ser. No. 16/695,980, filed Nov. 26, 2019, the contents of which are hereby incorporated by reference in their entirety. This application also claims the benefit of U.S. Prov. Pat. App. No. 63/030,845, filed May 27, 2020, the contents of which are hereby incorporated by reference in their entirety.

### FIELD

This disclosure relates to set ups for instruments, more particularly to a system for collecting and exchanging data from instruments.

### BACKGROUND

Users of test and measurement instruments, such as oscilloscopes, often use the instruments in complex setups that may include multiple instruments connected to one or more devices under test (DUTs), sometimes through specialized adapters, cables, or probes. Such an instrumentation setup may be used to perform a particular type of test or particular measurement on a DUT. Users often have a need to document the test setup so that it can be duplicated or recreated at a later time, for example to compare test data from multiple DUTs. Users also often need to obtain data from one or more test and measurement instruments involved in the setup, and need to share that data with other users, other test and measurement instruments, or other systems, either directly, or indirectly, for example via a network cloud-based service.

### BRIEF DESCRIPTION OF THE DRAWINGS

FIG. 1 shows an embodiment of a system having a communications device, a test and instrumentation set up and a server.

FIG. 2 shows an embodiment of a communications device.

FIG. 3 shows a flowchart of a method of capturing instrumentation data for storage and exchange.

FIG. 4 shows a flowchart of a method of capturing instrumentation data for storage and exchange.

### DETAILED DESCRIPTION

In embodiments, the disclosed technology includes an application on a smartphone or other communications device that allows users to perform an action, for example, take one or more pictures of the test and measurement instrumentation setup. This action triggers a system that combines the picture or pictures of the physical setup with other data from the oscilloscope or other test and measurement instruments. The picture of the physical setup may show where each instrument channel is connected, what type of hardware is being probed, meaning what type of device under test (DUT) is connected, a picture of the particular test and measurement instruments being used such as model number and serial number or other identifying information, and other characteristics of the physical setup. The data from the oscilloscope or other test and measurement instrument may include information on the instrument configuration, screenshots of the current state of the instrument, and structured waveform and measurement data files.

The following discussion will use several terms to encompass various topics. The term “communications device” means a device, such as a smartphone, tablets, computing devices with web cameras, or future devices that may take the place of smartphones, which may include a stand-alone digital camera, a circuit camera, microscope, or thermal camera with network and/or other connections. The communications device has at least one communications link that allows the device to communicate with the instrument being photographed, at least as far as sending a message to the instrument, and may use that same or other communications link to communicate with a remote server or storage. The communications device has a processor that executes code that enables it to communicate, a camera, an actuator to activate the camera, and a memory.

The term “photograph” encompasses any picture or image, such as visual images, thermal images, or images resulting from other techniques, such as spectrum techniques, captured by the camera on the communications device, typically stored as a digital image file. These terms will be used interchangeably to refer to this captured image or photograph.

The term “instrument” as used here means a device that gathers data, either a test and measurement device, referred to here as a measurement device, such as an oscilloscope, various kinds of meters, etc., or a sensor that gathers some sort of environmental data, such as temperature, wind speed, humidity, light intensity, sound levels, etc. These are just some examples and are in no way intended to limit the discussion to these particular examples.

The term “instrument data” means the data that the instrument has gathered and may include, but is not limited to: the instrument configuration and/or settings of any instrument involved in the set up; screen shots of the display of the instrument or instruments; the model and serial number of the instrument or instruments; a particular test or a particular step of a test that the instrument is performing on a device under test; the structured waveform applied to, or acquired from, the device under test; and the state of the instrument such as the CPU load, instrument set up information, enabled software licenses on the instrument, any other state-based information. In the case of a measurement instrument, the information may include connections between the instrument and any other devices, such as other measurement instruments; and measurement data files.

In the embodiment where the instrument is a sensor, the instrument data may include the type of the sensor, its current state, the make and model of the sensor, time and/or date stamps of samples stored by the sensor of whatever parameter it is sensing, etc.

The term “associated information” means information associated with the photograph that is gathered by the communications device. Some types of the associated information may include similar or the same information listed as being instrument data, but the difference between instrument data and associated information is that the instrument data is gathered by the instrument and the associated information is gathered by the communications device. In one embodiment, for example, the associated information may include instrument data, in an embodiment where the communications device receives the instrument data from the instrument directly, but the instrument data was initially gathered by the instrument. Associated information may include date and/or time stamps, location, manual or automatic tags, as well as many other types of information that may be gathered by the communications device at the time the photograph is taken.

“User information” as used here will typically be gathered from the communications device. It may identify the user, provide information for a user account, such as an email account, a cloud account or other storage account, including user names and passwords. This allows the photograph, associated data, and instrument data, if separate, to be stored in that user's account.

Using the application, a user can capture the physical test setup photographs and cause the instrument to send the instrumentation data. This collection of data containing images, photographs, waveforms, measurements, manual or automatic user tags, date and/or time stamps, location, etc. and may be stored locally on the smartphone or may be automatically sent to a central storage location.

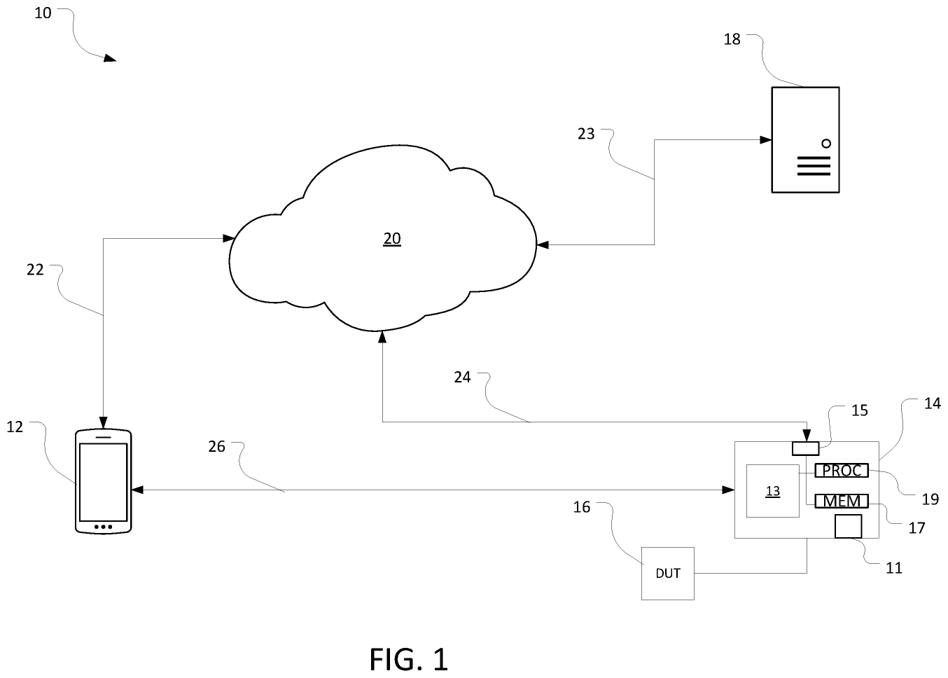

FIG. 1 shows an embodiment of a system 10 in which a communications device 12 and an instrument 14 are connected through a network 20 through communications links 22 and 24, respectively. A server 18 may be a proprietary server owned by the entity that owns the instrument 14 and possibly the user's communication device 12, or may be a cloud server on which the entity has accounts. The server 18 connects to the other devices through the network 20 by connection 23. In addition, the communications device 12 and the instrument 14 may have a communications link 26 through port 15. The instrument 14 may have a processor 19 and a memory 17, in addition to the display 13. The figure shows the communications link 26 as being bi-directional, but as discussed below, may actually be a one-way link between the communications device 12 and the instrument 14. Also, as shown the instrument 14 is connected to a device under test (DUT) 16, but this is just one embodiment and the instrument 14 could be a sensor, in which case the DUT would not be there.

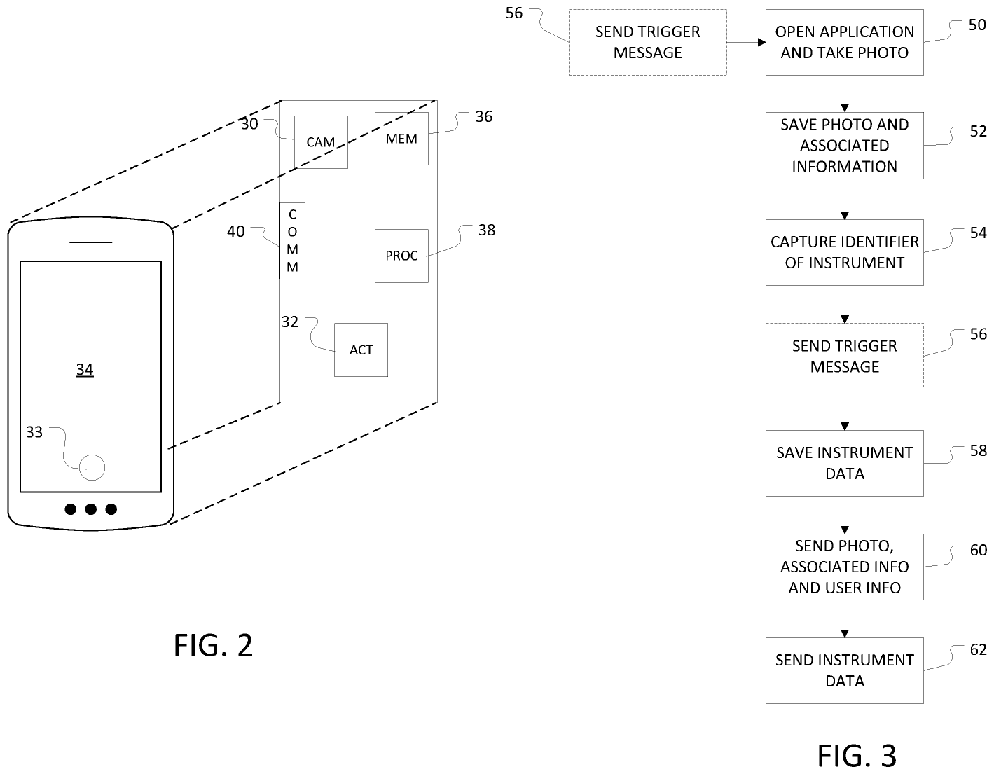

As mentioned above, the communications device may be what is commonly referred to as a smartphone, or whatever future embodiments of a smartphone entail. FIG. 2 shows one embodiment of such as device 12. The device has a camera 30 that will take the photograph of the instrument when the user activates the actuator. In current smartphones, for example, the actuator is an image of a button 33 on a user interface such as 34, which is typically a touch screen display. The activation of the actuator 32 will cause the device to send a message through the communications link 40 to the instrument. This will then result in a photograph that is stored in the memory 36, at least temporarily. A processor 38 controls these processes and may have a connection to the camera, the actuator, the memory, the communications link and the user interface.

FIG. 3 shows a flow chart for some embodiments of the process. In a first embodiment, the user opens an application on the communications device and takes a photograph of the instrument set up at 50, wherein the instrument set up includes at least one instrument and may include a DUT. The process then saves the photograph and associated information on the communications device at 52.

At 54, if necessary, the user may need to capture an identifier for the instrument. This may involve presenting the user with a list of possible instruments on the user interface of the communications device to allow the user to select the relevant instrument. Such selecting may be done by model number and serial number, or by another unique identifier of the instrument. Alternatively, the user could use the communications device, from within the application, to scan a QR code or a UPC on the instrument, or to read an RFID tag, where those codes or tags, such as 11 in FIG. 1, identify the instrument. One should note that the capture of the identifier could occur before or after the capturing of the photograph, as well as before or after sending the trigger message, as discussed below.

The identifier, if needed, would be included in the information associated with the photograph. One should note that capturing the identifier might not be needed. The system could use other means to identify the instrument, such as analysis of the photograph to identify the make and model of the instrument, etc.

The communications device uses the taking of the photograph as an indication to send a trigger message to the instrument at 56. The trigger message triggers the instrument to save the instrument data at 58. In one embodiment, the communications device sends the photograph, associated information, and user information through the network to the server 18 from FIG. 1 at 60. The instrument would then send the information through a separate link to the network at 62 to be combined at the server or other location remote from the communications device. This may be due to security concerns for proprietary information, etc.

In another embodiment, the instrument receives the trigger message at 56, saves the instrument data at 58, and then transmits it back to the communications device. The communications device then includes the instrument data in the information associated with the photograph and then sends the information to the server 18 at 60, making 62 an optional step. The processor 19 of the instrument may save the instrument data in the memory 17, as the processor executes instructions that cause the processor to operate in this manner.

In addition, in some embodiments, the application on the communications device can emulate a memory device, such as a USB flash drive, such that it can use the local memory on the communications device to act as a data transfer mechanism for instrumentation set ups or sensors. This data transfer mechanism may be used to move data from one device to another, such as from one test and measurement instrument to another, or to use the data connection in the phone to transfer the data to a central storage location as mentioned above. When used as a USB memory, the communications device may be connected to a different instrument in a different set up later, and the information could then be uploaded from the communications device to allow the current set up to replicate the previous instrument set up. In addition, the application may also recall the saved setup and data onto that instrument or another instrument from the remote location. Users could also share information between themselves in addition to storing the information on the server and giving other users access.

While the flow of the process of FIG. 3 may lead one to conclude that those processes must appear in a particular order, no such limitation is intended nor should one be inferred. For example, the actuation signal of the communications device may occur nearly simultaneously with the sending of the trigger message, from the communications device to the instrument, with the management of the photo and associated information occurring later.

In another embodiment, the instrument could send the trigger message to the communications device and cause the communications device to take the image, with the instrument triggering itself to save data. The instrument triggering itself could be from a dedicated button or other control on the instrument, or may occur as result of events on the instrument. The user may already have the application open on the communications device and when it receives the trigger message, the communications device takes the picture. In other embodiments, the user may have set up a communications device equipped with a digital camera on a tripod or other fixed mounting point, and the instrument sends the trigger message to the device to take the photo.

Many test instruments have triggers, sometimes referred to as acquisition triggers, especially in the context of an oscilloscope. The instrument could start the whole sequence. The acquisition trigger on the instrument, when activated, would then cause the instrument to send the trigger message. Some instruments have a feature that causes the instrument to save data upon a trigger. The instrument would then save in response to the acquisition trigger. FIG. 3 shows the process 56 in dashed boxes because it could occur in a different sequence than what may otherwise be implied.

Embodiments of the disclosed technology may use various connection options to the oscilloscope or other test and measurement instrument, in order to initiate a measurement and/or collect and transfer data. For example, connection options between the smartphone application or other embodiments of the communications device and the test and measurement instrument may include local LAN, Cloud connected, USB connected, and other communication interfaces such as Wi-Fi, Bluetooth®, Bluetooth® Low Energy (BLE), Near-Field Communication (NFC), Z-wave, cellular, infrared, etc. This link may also consist of the images of the instrument identifier, such as the QR, UPC, OCR (optical character recognition), or image processing that can recreate the waveforms from the images of the waveform. The identifiers could be used to transfer data between the instrument and the communications device.

The disclosed technology can apply to all test and measurement instrumentation. Such instrumentation can even include sensors. For example, embodiments of the disclosed technology also include using the smartphone application to take a picture of a sensor at 50, and saves the photograph at 52. This photographing action sends the trigger message at 56 to capture the current state of the sensor at 58, either at the sensor or at the communications device. The photographing action may also capture an identifier of the sensor at 54. The data being sent to a server at 60 may take the form of creating a streaming data bucket for that sensor in a cloud-based service for data collection, visualization, and analysis, for example the services offered by Initial State at www.initialstate.com.

Many types of instrument data from the instrument can be bundled with the photograph. Things like tagging, time/date, location, and a host of other things may all be part of the data package that is collected and saved or transferred, whether captured at the instrument or the communications device. As mentioned previously, associated information is gathered by the communications device and may include the instrument data, but the instrument data is initially gathered by the instrument.

Furthermore, other embodiments of the disclosed technology may not include taking a photograph or otherwise capturing an image of the test and measurement instrumentation setup and/or the sensor setup. That is, some users of the system may not need or want to have a photograph of the physical test environment setup (e.g., device under test, test instrument or instruments, connected cable configuration, etc.) every time they want to initiate a transfer of a collection of data from the test and measurement instrument to a cloud account, for example. In these embodiments, any action performed on the communications device can operate to initiate a transfer of data. For example, rather than a user activating an actuator on the communications device to take a photograph, which then causes the communications device to send a trigger message to the instrument as discussed above, a user may instead operate a button on the communications device, touch a particular area of the communications device screen, perform a particular gesture or facial movement recognized by the communication device, shake or otherwise move the communications device in a particular way, bring the communications device within a certain proximity of the test and measurement instrument, or perform any other action recognized by an application on the communications device. Recognition of this action can then cause the communications device to send a trigger message to the test and measurement instrument to save instrument data.

In these embodiments, the communications device may not include the camera 30, the actuator 32, or the image of a button 33, as depicted in FIG. 2, and the communications device may not store a photograph in memory.

Also, in relation to these embodiments, the term “associated data” means information gathered by the communications device that is associated with the instrument data triggered to be saved upon recognition of the action performed by the user on the communications device. For example, in these embodiments, associated information may include date and/or time stamps, location, manual or automatic tags, temperature, humidity, or other ambient environmental conditions, as well as many other types of information that may be gathered by the communications device at the time the recognized action is performed. In these embodiments, the collection, storage, and transfer of associated information is optional; that is, the communications device may be used simply to initiate the transfer of instrument data from the test and measurement instrument, and/or to link the instrument data to the user's storage or cloud account.

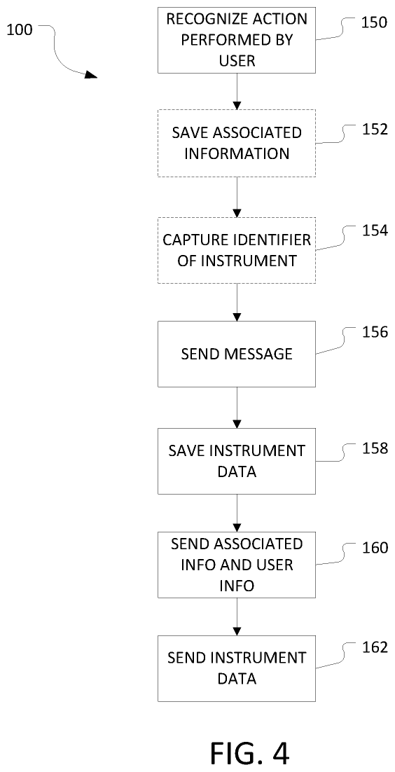

FIG. 4 shows a flow chart of a process according to some of these other embodiments. At operation 150, the communications device recognizes a particular action performed by the user, examples of which are discussed above. At operation 152, associated information, not including a photograph, is optionally saved on the communications device.

At operation 154, if necessary, the user may need to capture an identifier for the test instrument. This may be accomplished as discussed above with respect to operation 54 of FIG. 3, except that scanning a QR code to identify the instrument is unlikely to be used in these embodiments.

After recognition of the action performed by the user, at 156, the communications device sends a message to the instrument, which causes the instrument to save instrument data at 158.

At 160, associated information, if any, and user information are sent to the server 18 of FIG. 1. At 162, instrument data is sent to the server 18 to be linked to the user's account.

In some embodiments, at 160, the communications device sends the associated information and user information through the network 20 to the server 18, via communications link 22, as shown in FIG. 1. At 162, the instrument sends the instrument data through the network 20 to the server 18, via communications link 24, as shown in FIG. 1. Then, the instrument data is combined with the associated information at the server 18 and linked to the user's account included in the user information.

In other embodiments, at 160, the communications device sends associated information, if any, and user information to the instrument 14, via communications link 26, as shown in FIG. 1. The instrument may combine the associated information and user information with the instrument data, and, at 162, send this combined collection of data through the network 20 to the server 18, via communications link 24, as shown in FIG. 1. The collection of data may be linked to the user's account included in the user information.

And in still other embodiments, at 162, the instrument may send the instrument data to the communications device, and at 160, the communications device sends the instrument data combined with the associated information and user information through the network 20 to the server 18.

In this disclosure, the singular forms “a,” “an,” and “the” include plural referents unless the context dictates otherwise. The term “or” as used here is meant to be inclusive and means either, any, several, or all of the listed items. The terms “comprises,” “comprising,” “includes,” “including,” or other variations thereof, are intended to cover a non-exclusive inclusion such that a process, method, or product that comprises a list of elements does not necessarily include only those elements, but may include other elements not expressly listed or inherent to such a process, method, article, or apparatus. Relative terms, such as “about,” “approximately,” “substantially,” and “generally,” are used to indicate a possible variation of ±10% of a stated or understood value.

The aspects of the present disclosure are susceptible to various modifications and alternative forms. Specific aspects have been shown by way of example in the drawings and are described in detail herein. However, one should note that the examples disclosed herein are presented for the purposes of clarity of discussion and are not intended to limit the scope of the general concepts disclosed to the specific aspects described herein unless expressly limited. As such, the present disclosure is intended to cover all modifications, equivalents, and alternatives of the described aspects in light of the attached drawings and claims.

References in the specification to aspect, example, etc., indicate that the described item may include a particular feature, structure, or characteristic. However, every disclosed aspect may or may not necessarily include that particular feature, structure, or characteristic. Moreover, such phrases are not necessarily referring to the same aspect unless specifically noted. Further, when a particular feature, structure, or characteristic is described in connection with a particular aspect, such feature, structure, or characteristic can be employed in connection with another disclosed aspect whether or not such feature is explicitly described in conjunction with such other disclosed aspect.

Additionally, this written description refers to particular features. One should understand that the disclosure in this specification includes all possible combinations of those particular features. For example, where a particular feature is disclosed in the context of a particular aspect, that feature can also be used, to the extent possible, in the context of other aspects.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid-state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description refers to particular features. One should understand that the disclosure in this specification includes all possible combinations of those particular features. For example, where a particular feature is disclosed in the context of a particular aspect, that feature can also be used, to the extent possible, in the context of other aspects.

In addition, when this application refers to a method having two or more defined steps or operations, the defined steps or operations can be carried out in any order or simultaneously, unless the context excludes those possibilities.

### Examples

Illustrative examples of the technologies disclosed herein are provided below. An embodiment of the technologies may include any one or more, and any combination of, the examples described below.

Example 1 is a method of capturing instrument data using a communications device, comprising: recognizing an action performed by a user on the communication device; one of either transmitting or receiving a trigger message between the communications device and at least one instrument; storing instrument data in a memory on the at least one instrument; and transmitting the instrument data and user information to a network.

Example 2 is the method of example 1, further comprising storing the instrument data in a data store on the network associated with the user information.

Example 3 is the method of either examples 1 or 2, wherein the communications device transmits the trigger message to the at least one instrument, in response to recognizing the action performed by the user on the communication device.

Example 4 is the method of any of examples 1 to 3, further comprising: capturing an identifier for the at least one test instrument; and transmitting the identifier to the network as part of the instrument data.

Example 5 is the method of any of examples 1 to 4, further comprising saving associated information in a memory on the communications device.

Example 6 is the method of any of examples 1 to 5, wherein the associated information does not include a photograph.

Example 7 is the method of any of examples 1 to 6, wherein the associated information comprises information gathered by the communications device that is associated with the instrument data.

Example 8 is the method of any of examples 1 to 7, wherein the associated information comprises at least one of a date stamp, a time stamp, a location, a manual tag, an automatic tag, temperature data, humidity data, or other ambient environmental conditions associated with the instrument data.

Example 9 is the method of any of examples 1 to 8, further comprising transmitting the associated information to the network.

Example 10 is the method of any of examples 1 to 9, wherein transmitting the instrument data and user information to a network comprises transmitting the instrument data from the instrument to a server, wherein transmitting the associated information to the network comprises transmitting the associated information from the communications device to the server, further comprising: combining the instrument data and the associated information on the server; and storing the combined instrument data and associated information in a data store on the server accessed by the user information.

Example 11 is the method of any of examples 1 to 9, further comprising receiving associated information from the communications device at the instrument and combining the associated information with the instrument data in the instrument before transmitting the instrument data and user information to the network, wherein transmitting the instrument data and user information to the network comprises transmitting the combined instrument data and associated information to a server, further comprising storing the combined instrument data and associated information in a data store on the server accessed by the user information.

Example 12 is the method of any of examples 1 to 9, wherein transmitting the instrument data and user information to the network comprises transmitting the instrument data from the instrument to the communications device, combining the instrument data with associated information on the communications device, and transmitting the combined instrument data and associated information from the communications device to a server, further comprising storing the combined instrument data and associated information in a data store on the server accessed by the user information.

Example 13 is the method of any of examples 3 to 12, wherein transmitting the trigger message from the communications device to the at least one instrument comprises sending the trigger message to a sensor and instrument data gathered from the instrument includes sensor data.

Example 14 is the method of example 13, further comprising creating a streaming data bucket for the sensor on a cloud-based service.

Example 15 is the method of any of examples 3 to 12, wherein transmitting the trigger message to the at least one instrument comprises sending the trigger message to a test and measurement device, and instrument data comprises at least one of: a configuration of the test and measurement device; waveform data; measurement data; connections for channels on the test and measurement device; a type of a device under test; time stamp; date stamp; state information of the test and measurement device; and location.

Example 16 is the method of example 15, wherein the test and measurement device comprises an oscilloscope.

Example 17 is a test system, comprising: a test and measurement device including: at least one communications link; a memory; and a processor configured to execute instructions that cause the processor to: receive a message through the communications link; save instrument data into the memory; and transmit the instrument data to a remote location; and a communications device including: at least one communications link; a memory; and a processor configured to execute instructions that cause the processor to: recognize an action performed by a user; send the message to the test and measurement device; store associated information including user information; and transmit the user information to the remote location.

Example 18 is the test system of example 17, wherein the communications device comprises one of a smart phone, a tablet, or a portable computing device.

Example 19 is the test system of either of examples 17 or 18, wherein each of the at least one communications links comprises at least one of the group consisting of: a cellular connection; wireless fidelity (Wi-Fi); near field communications (NFC); Ethernet; a USB connection; Z-wave; Bluetooth®; and Bluetooth® Low Energy.

Example 20 is the test system of any of examples 17 to 19, wherein the remote location comprises a cloud-based account associated with the user information.

The previously described versions of the disclosed subject matter have many advantages that were either described or would be apparent to a person of ordinary skill. Even so, all of these advantages or features are not required in all versions of the disclosed apparatus, systems, or methods.

Although specific embodiments have been illustrated and described for purposes of illustration, it will be understood that various modifications may be made without departing from the spirit and scope of the disclosure. Accordingly, the invention should not be limited except as by the appended claims.

1. A method of capturing instrument data using a communications device, comprising:
recognizing an action performed by a user on the communication device;
one of either transmitting or receiving a trigger message between the communications device and at least one instrument;
storing instrument data in a memory on the at least one instrument; and
transmitting the instrument data and user information to a network.

2. The method as claimed in claim 1, further comprising storing the instrument data in a data store on the network associated with the user information.

3. The method as claimed in claim 1, wherein the communications device transmits the trigger message to the at least one instrument, in response to recognizing the action performed by the user on the communication device.

4. The method as claimed in claim 1, further comprising:
capturing an identifier for the at least one test instrument; and
transmitting the identifier to the network as part of the instrument data.

5. The method as claimed in claim 1, further comprising saving associated information in a memory on the communications device.

6. The method as claimed in claim 5, wherein the associated information does not include a photograph.

7. The method as claimed in claim 5, wherein the associated information comprises information gathered by the communications device that is associated with the instrument data.

8. The method as claimed in claim 5, wherein the associated information comprises at least one of a date stamp, a time stamp, a location, a manual tag, an automatic tag, temperature data, humidity data, or other ambient environmental conditions associated with the instrument data.

9. The method as claimed in claim 5, further comprising transmitting the associated information to the network.

10. The method as claimed in claim 9, wherein transmitting the instrument data and user information to a network comprises transmitting the instrument data from the instrument to a server, wherein transmitting the associated information to the network comprises transmitting the associated information from the communications device to the server, further comprising:
combining the instrument data and the associated information on the server; and
storing the combined instrument data and associated information in a data store on the server accessed by the user information.

11. The method as claimed in claim 1, further comprising receiving associated information from the communications device at the instrument and combining the associated information with the instrument data in the instrument before transmitting the instrument data and user information to the network, wherein transmitting the instrument data and user information to the network comprises transmitting the combined instrument data and associated information to a server, further comprising storing the combined instrument data and associated information in a data store on the server accessed by the user information.

12. The method as claimed in claim 1, wherein transmitting the instrument data and user information to the network comprises transmitting the instrument data from the instrument to the communications device, combining the instrument data with associated information on the communications device, and transmitting the combined instrument data and associated information from the communications device to a server, further comprising storing the combined instrument data and associated information in a data store on the server accessed by the user information.

13. The method as claimed in claim 3, wherein transmitting the trigger message from the communications device to the at least one instrument comprises sending the trigger message to a sensor and instrument data gathered from the instrument includes sensor data.

14. The method as claimed in claim 13, further comprising creating a streaming data bucket for the sensor on a cloud-based service.

15. The method as claimed in claim 3, wherein transmitting the trigger message to the at least one instrument comprises sending the trigger message to a test and measurement device, and instrument data comprises at least one of: a configuration of the test and measurement device; waveform data; measurement data; connections for channels on the test and measurement device; a type of a device under test; time stamp; date stamp; state information of the test and measurement device; and location.

16. The method as claimed in claim 15, wherein the test and measurement device comprises an oscilloscope.

17. A test system, comprising:
a test and measurement device including:
at least one communications link;
a memory; and
a processor configured to execute instructions that cause the processor to:
receive a message through the communications link;
save instrument data into the memory; and
transmit the instrument data to a remote location; and
a communications device including:
at least one communications link;
a memory; and
a processor configured to execute instructions that cause the processor to:
recognize an action performed by a user;
send the message to the test and measurement device;
store associated information including user information; and
transmit the user information to the remote location.

18. The test system as claimed in claim 17, wherein the communications device comprises one of a smart phone, a tablet, or a portable computing device.

19. The test system as claimed in claim 17, wherein each of the at least one communications links comprises at least one of the group consisting of: a cellular connection; wireless fidelity (Wi-Fi); near field communications (NFC); Ethernet; a USB connection; Z-wave; Bluetooth®; and Bluetooth® Low Energy.

20. The test system as claimed in claim 17, wherein the remote location comprises a cloud-based account associated with the user information.
